(19) United States
(12) Patent Application Publication
(10) Pub. No.: US 2002/0058343 A1
(43) Pub. Date: May 16, 2002

(54) Evaluation method of ferroelectric capacitor and wafer mounted with evaluation element

(76) Inventors: Alexei Gruverman, Kanagawa (JP); Masahiro Tanaka, Kanagawa (JP)

Correspondence Address: David R. Metzger, Esq., SONNENSCHEIN NATH & ROSENTHAL, Wacker Drive Station, Sears Tower, P.O. Box#061080, Chicago, IL, 60606-1080, US

(21) Appl. No.: 09/865,265

(22) Filed: May 25, 2001

(30) Foreign Application Priority Data
May 26, 2000 (JP) P2000-155748

(51) Int. Cl. H01L 21/00

(52) U.S. Cl. 438/3

(57) ABSTRACT

A method is provided for evaluating a ferroelectric capacitor by examining a structure in a prescribed area on a surface of a ferroelectric membrane using a piezo-response mode of a scanning force microscope. The method adopts a layered structure, in which an electrode and the ferroelectric membrane form a pseudo ohmic contact, and comprises the steps of: inducing a localized polarization inversion in a selected crystal grain in the ferroelectric membrane by imposing a voltage pulse having a prescribed polarity; determining a retention time by obtaining a piezo-response image for a prescribed time till a complete inversion of a write domain; and determining a retention characteristic by measuring a time till a complete disappearance of a switched domain or by measuring a time-dependency at a region where the polarization inversion are being retained.

### RELATED APPLICATION DATA

This application claims priority to Japanese Patent Application JP 2000-155748, and the disclosure of that application is incorporated herein by reference to the extent permitted by law.

### BACKGROUND OF THE INVENTION

1. Field of the Invention

The present invention relates to an evaluation method of a ferroelectric capacitor and a wafer mounted with an evaluation element, and more particularly to an evaluation method of a retention characteristic of a ferroelectric capacitor and a wafer mounted with an evaluation element by which the retention characteristic of a capacitor is evaluated.

2. Description of the Related Art

A conventional evaluation method of a retention characteristic of a ferroelectric capacitor has been performed by forming a ferroelectric thin film on a lower electrode and forming an upper electrode on the formed ferroelectric thin film, namely by completing the structure of a capacitor at first, and then by measuring the hysteresis of the capacitor by imposing a pulse voltage between the upper electrode and the lower electrode.

In recent years, a ferroelectric thin film has attracted attention as an application technology to a new generation non-volatile storage device. In the commercialization of a ferroelectric storage device, the improvement of life characteristics of a ferroelectric capacitor such as the retention characteristic thereof, the fatigue thereof, the leakage characteristic thereof, and the dielectric breakdown thereof is required. In the evaluation of the ferroelectric capacitor, it is an important factor that an electrode material controls the electrical parameters of the ferroelectric capacitor (see H. N. Al-Shareef et al, J. Mater. Res. 9, No. 11, 2968(1994)). The interface between a ferroelectric membrane and an electrode is strongly influenced by the dielectric characteristics of the ferroelectric membrane and the distribution state of an internal field.

The retention characteristic is defined as ability such that a ferroelectric capacitor holds a fixed polarization state after a voltage change. Such ability is determined by platinum (Pt) electrodes and a lead zirconate titanate (PZT) series ferroelectric membrane. The aforesaid platinum of the platinum electrodes is widely used as a general electrode material, and it shows retention-loss characteristic (see J. F. Scott et al, Appl. Phys. 66, 1444 (1989); R. Nasby et al, Integrated Ferroelectrics 2, 91 (1992)). The characteristic of the ferroelectric capacitor can be described by means of the existence of an internal field for forming a depression layer at the interface between the membrane and the electrodes.

The depression layer appears at a membrane/electrode interface as a result of a semiconductor characteristic of a Perovskite ferroelectric membrane. When a metal is contacted with a semiconductor, because a work function of the metal and a work function of the semiconductor differ from each other, a potential barrier and a space charge distribution are formed at the interface. The internal field in a depression region works as a trigger of the formation of a core in a region where polarity is opposite after changing the voltage. In such a way, the retention-loss process begins. On the contrary, if the metal and the semiconductor have work functions that form an ohmic contact, the retention effect becomes important because there is no built-in field.

### SUMMARY OF THE INVENTION

As described above, the conventional evaluation of the retention characteristic of a ferroelectric capacitor evaluates the hysteresis characteristic of a ferroelectric membrane by imposing an electrode pulse between an upper electrode and a lower electrode after the formation of a capacitor structure, namely a layered structure of the lower electrode, the ferroelectric membrane and the upper electrode. Accordingly, it is difficult to evaluate the retention characteristic of a capacitor at an early stage of capacitor manufacturing processes.

An object of the present invention is to provide an evaluation method of a ferroelectric capacitor and a wafer for evaluation, both capable of resolving the aforesaid problems.

An evaluation method in accordance with one embodiment of the present invention is a method for evaluating a ferroelectric capacitor by examining a structure in a prescribed area on a surface of a ferroelectric membrane using a piezo-response mode of a scanning force microscope, wherein: the method adopts a layered structure, in which an electrode and the ferroelectric membrane form a pseudo ohmic contact, in an evaluation element, and the method comprises the steps of: inducing a localized polarization inversion in a selected crystal grain in the ferroelectric membrane by imposing a voltage pulse having a prescribed polarity through a fixed test chip; determining a retention time by obtaining a piezo-response image for a prescribed time till a complete inversion of a write domain; and determining a retention characteristic by measuring a time till a complete disappearance of a switched domain or by measuring a time-dependency at a region where the polarization inversion are being held.

According to the aforesaid method for evaluating a ferroelectric capacitor, the evaluation of the retention characteristic of the capacitor is performed in a state such that a lower electrode and a ferroelectric membrane are layered after the ferroelectric membrane has been formed before an upper electrode is formed. Consequently, it becomes possible to evaluate the performance of a capacitor halfway through the manufacturing processes of the capacitor.

A wafer mounted with an evaluation element according to one embodiment of the present invention is for an evaluation of a retention characteristic of a capacitor comprising: a lower electrode formed on a semiconductor wafer; and a ferroelectric membrane having a pseudo ohmic contact formed on the lower electrode.

According to the aforesaid wafer mounted with the evaluation element, it becomes possible to perform the evaluation of the performance of a ferroelectric capacitor before the completion of the capacitor by means of an evaluation element composed of a lower electrode and a ferroelectric membrane. Consequently, because defects becomes possible to be discovered early in manufacturing processes, the reduction of a production cost is enabled by the early stage discovery of the defects when the defects has occurred.

### BRIEF DESCRIPTION OF THE DRAWINGS

The above and other objects, features and advantages of the present invention will become more apparent from the following description of the presently preferred exemplary embodiments of the invention taken in conjunction with the accompanying drawings, in which:

FIGS. 1a-1d are views showing observed images of a SrBi₂Ta₂O₉(SBT) /Pt hetero structure in which a retention-loss can be observed;

FIGS. 2a-2d are views showing observed images of piezo responses indicating the stability of a negative domain in SrBi₂Ta₂O₉(SBT)/Ir hetero structure after localized polarization inversion (poling);

FIGS. 3a-3d are views showing observed images of piezo responses indicating the stability of a positive domain in SrBi₂Ta₂O₉(SBT)/Ir hetero structure after localized polarization inversion (poling); and

FIGS. 4A and 4B are views showing retention polarization expressed as a function of time in a positive domain and a negative domain in a SBT membrane/Pt membrane and a SBT membrane/Ir membrane.

### DESCRIPTION OF THE PREFERRED EMBODIMENTS

A preferred embodiment of an evaluation method of a ferroelectric capacitor in accordance with one embodiment of the present invention is described as under.

The method for evaluating a ferroelectric capacitor is an evaluation method in which the following processes are performed. In the evaluation method, the evaluation is performed by examining a structure in a prescribed area on a surface of a ferroelectric membrane with using a piezo-response mode of a scanning force microscope. An evaluation element having a layered structure, in which an electrode and a ferroelectric membrane form a pseudo ohmic contact, is used as the evaluation element to be used in the evaluation method. Then, a localized polarization inversion is induced in a selected crystal grain in the ferroelectric membrane by the imposition of a voltage pulse having a prescribed polarity through a fixed test chip, and a retention time is determined by the acquisition of a piezo-response image for a prescribed time till a complete inversion of a write domain. A retention characteristic is determined by the measurement of a time till a complete disappearance of a switched domain or by the measurement of a time-dependency at a region where the polarization inversion are being retained.

In one embodiment, the present invention utilizes the fact that an electrical characteristic related to joining of an electrode with a ferroelectric membrane plays an important role on an estimation of the retention characteristic of a ferroelectric capacitor. The aforesaid electrical characteristic is determined by difference between a work function of the electrode and a work function of the ferroelectric substance membrane. Moreover, a Schottky barrier is formed by a p-type semiconductor ferroelectric membrane having the work function larger than that of a metal electrode. Then, disappearance of the internal field in the vicinity of the ferroelectric membrane/electrode interface is triggered by the switching to a negative polarization.

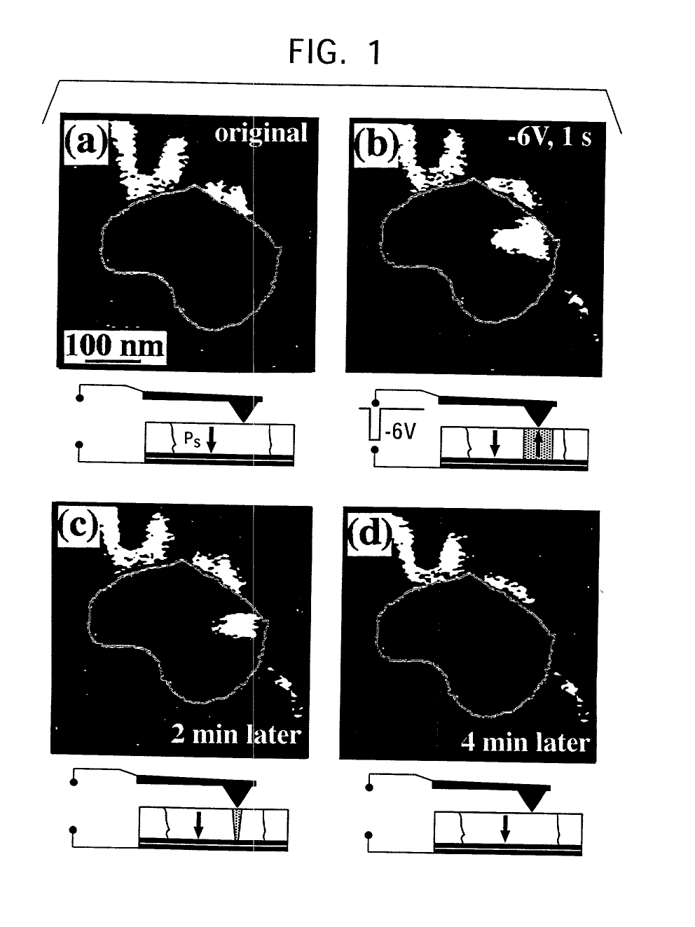

The effect is shown in FIGS. 1a-1d. FIGS. 1a-1d show images of the observation results of a SrBi₂Ta₂O₉(SBT)/Pt hetero structure in which a retention-loss can be observed by means of a scanning force microscope. Among the images, as shown in FIG. 1a, no polarization inversion occurs in a state before a voltage pulse is imposed. And, as shown in FIG. 1b, a spontaneous polarization inversion (a white part at a central part of the crystal in the figure) is observed in the domain by the imposition of a voltage pulse of −6V. The fact is known as formation of a Schottky type contact (see J. F. Scott et al, Ferroelectrics 225, 83(1999)). Furthermore, as shown in FIG. 1c, the polarization inversion (the white part at the central part of the crystal in the figure) still occurs in a state such that two minutes have passed after the localized polarization inversion (poling). After that, as shown in FIG. 1d, disappearance of the polarization inversion was observed in a state such that four minutes had passed after the localized polarization inversion (poling) occurred.

As described above, it becomes possible to perform the evaluation of the retention characteristic of a ferroelectric capacitor for a short time.

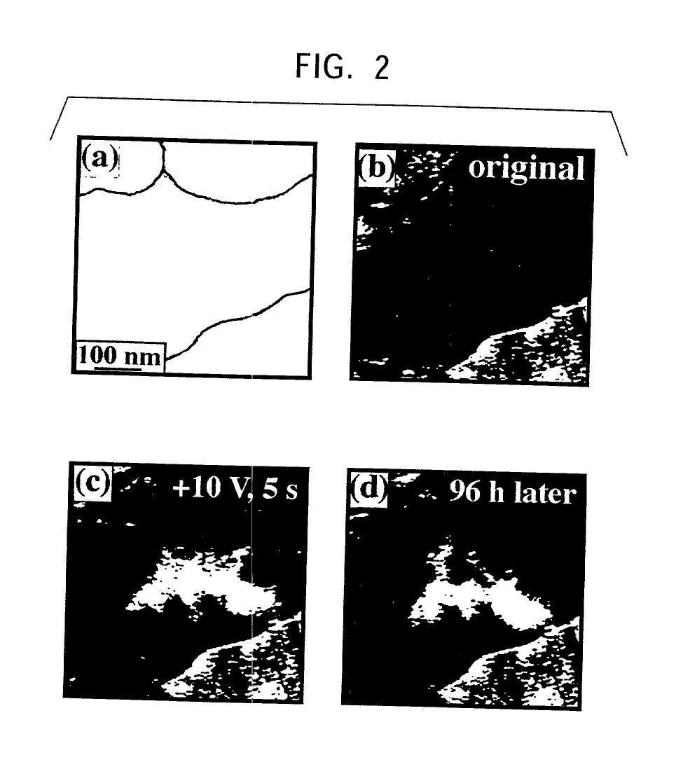

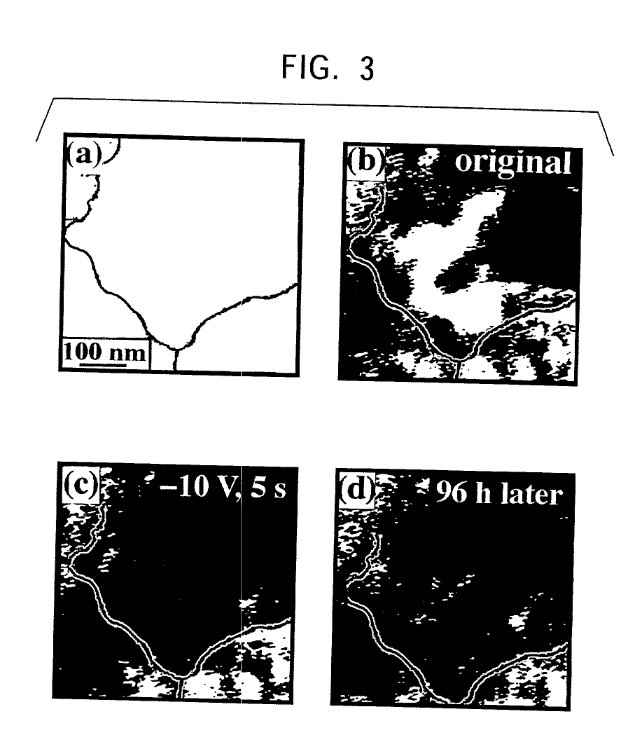

Next, the stability of a negative domain and a positive domain of a structure such that a SBT membrane is deposited on an Ir electrode is described with reference to FIGS. 2a-2d and 3a-3d. The stability was evaluated by means of the piezo-response mode of a scanning force microscope.

As shown in FIGS. 2a-2d, with regard to the retention characteristic of a SBT membrane (negative domain) on an Ir electrode, disappearance of the polarization inversion (a white part in a central part of the figures) cannot almost be observed till a state shown in FIG. 2d after 96 hours from an initial state shown in FIG. 2b. That is, it is shown that a stable retention characteristic is being maintained for 96 hours after writing has been performed by the imposition of an external pulse voltage of 10V. Similarly, with regard to the retention characteristic of a SBT membrane (a positive domain) on a Pt electrode shown in FIGS. 3a-3d, although a polarization inversion (a white part in a central part of FIG. 3b) is generated in an initial state as shown in FIG. 3b, it is shown that a stable retention characteristic is held even in a state shown in FIG. 3d after 96 hours from a localized polarization inversion (poling). As described above, the retention characteristic of the SBT membrane on the Ir electrode is superior to that of the SBT membrane on the Pt electrode. Incidentally, FIG. 2a and FIG. 3a show the states before the imposition of the voltages, and they show grain boundary parts with black lines and crystal grain parts, at which the polarization inversion does not occur yet though, with white color for the facilitation of observation.

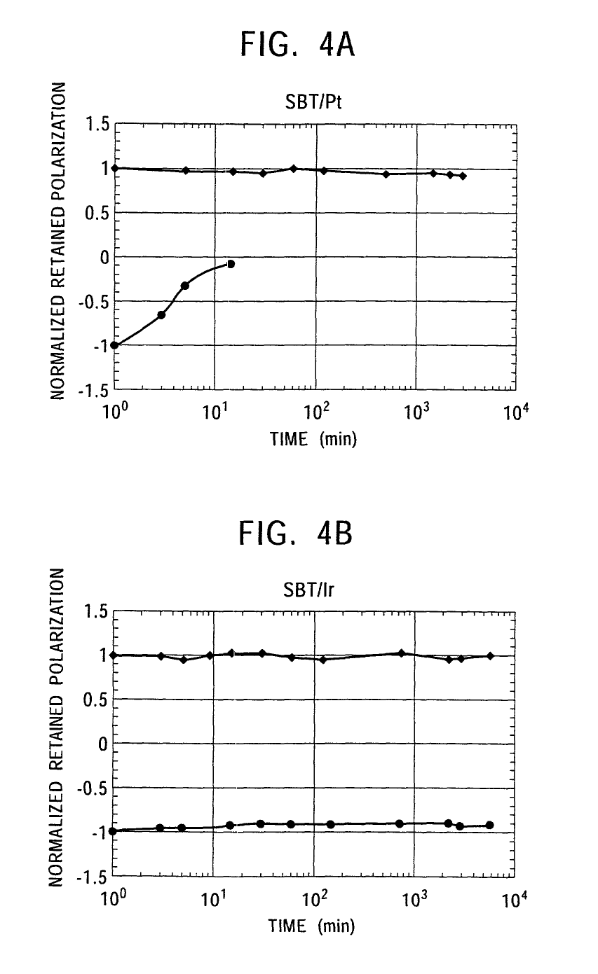

Now, difference between the retention characteristic of the SBT/Pt membrane and the retention characteristic of the SBT/Ir membrane is described by means of FIGS. 4A and 4B. Incidentally, FIG. 4A is a view showing the retention characteristic of the SBT/Pt membrane, and the ordinate axis thereof indicates a normalized retained polarization and the abscissa axis thereof indicates time. Moreover, FIG. 4B is a view showing the retention characteristic of the SBT/Ir membrane, and the ordinate axis thereof indicates a normalized retained polarization and the abscissa axis thereof indicates time.

As shown in FIGS. 4A and 4B, the retention characteristic of the SBT/Ir membrane is stable for a longer period in comparison with the retention characteristic of the SBT/Pt membrane. In particular, the stability of the retention characteristic of the SBT/Ir membrane to a negative domain is superior.

The Ir electrode is easy to be oxidized during membrane forming processes. The influence of the oxidization leads to increase of the work function of the electrode, and leads to formation of the ohmic contact. As a result, the internal field does not enter inside of the membrane. Besides, the retention characteristic of a capacitor having a structure of Ir electrode/SBT membrane/Ir electrode is improved in comparison with the retention characteristic of a capacitor having a structure of Pt electrode/SBT membrane/Pt electrode.

The evaluation method of a ferroelectric capacitor in accordance with the present embodiment such as described above may be performed in manufacturing processes of a ferroelectric membrane capacitor in a manufacturing line of a semiconductor device, for example. Alternatively, the evaluation method is performed after a ferroelectric membrane of the ferroelectric capacitor has been formed.

As described above, because the retention characteristic of a ferroelectric capacitor can be evaluated halfway through the manufacturing processes before the upper electrode of the capacitor is formed according to embodiments of the present invention, it becomes possible to find defects in the manufacturing processes in early stages. Conventionally, the manufacturing process of forming the upper electrode is performed in a state such that the defect had been already occurred but not detected. However, according to the present invention, the defect may be discovered before formation of the upper electrode by finding the defect at early stage. Consequently, reduction of a production cost is enabled.

A wafer mounted with an evaluation element in accordance with one embodiment of the present invention is described in the following.

In the wafer mounted with an evaluation element, the evaluation element is formed, for example, at a prescribed position on a semiconductor wafer. The evaluation element comprises a lower electrode formed, for example, simultaneously with a lower electrode of a ferroelectric capacitor functioning as a device, and a ferroelectric membrane formed on the lower electrode. Besides, the lower electrode and the ferroelectric membrane have a pseudo ohmic contact to each other.

In the wafer mounted with the aforesaid evaluation element, by means of the evaluation element comprising the lower electrode and the ferroelectric membrane, it becomes possible to carry out the performance evaluation of the ferroelectric capacitor before completion of the capacitor manufacturing process. Consequently, because it becomes possible to discover defects in early stages in the manufacturing processes, the reduction of a manufacturing cost is enabled by the early stage discovery of the defects in the case if the defects has occurred.

Although the present invention has been described in its preferred form with a certain degree of particularity, obviously many changes and variations are possible therein. It is therefore to be understood that the present invention may be practiced than as specifically described herein without departing from scope and the sprit thereof.

What is claimed is:

1. A method for evaluating a ferroelectric capacitor by examining a structure in a prescribed area on a surface of a ferroelectric membrane using a piezo-response mode of a scanning force microscope, wherein:
said method adopts a layered structure, in which an electrode and the ferroelectric membrane form a pseudo ohmic contact, in an evaluation element, and
said method comprises the steps of:
inducing a localized polarization inversion in a selected crystal grain in the ferroelectric membrane by imposing a voltage pulse having a prescribed polarity through a fixed test chip;
determining a retention time by obtaining a piezo-response image for a prescribed time till a complete inversion of a write domain; and
determining a retention characteristic by measuring a time till a complete disappearance of a switched domain or by measuring a time-dependency at a region where the polarization inversion are being retained.

2. The method according to claim 1, wherein said evaluation element comprises a lower electrode, and a ferroelectric thin film having a pseud ohmic contact, the ferroelectric thin film being deposited on the lower electrode.

3. A method for evaluating a ferroelectric capacitor, wherein said method performs an evaluation procedure during a manufacturing process of a ferroelectric membrane capacitor in a manufacturing line of a semiconductor device or after formation of the ferroelectric membrane, said evaluation procedure being for evaluating the ferroelectric capacitor by examining a structure in a prescribed area on a surface of the ferroelectric membrane using a piezo-response mode of a scanning force microscope, wherein:
said evaluation procedure adopts a layered structure, in which an electrode and the ferroelectric membrane form a pseudo ohmic contact, in an evaluation element, and
said evaluation procedure comprises the steps of:
inducing a localized polarization inversion in a selected crystal grain in the ferroelectric membrane by imposing a voltage pulse having a prescribed polarity through a fixed test chip;
determining a retention time by obtaining a piezo-response image for a prescribed time till a complete inversion of a write domain; and
determining a retention characteristic by measuring a time till a complete disappearance of a switched domain or by measuring a time-dependency at a region where the polarization inversion are being retained.

4. A wafer mounted with an evaluation element for an evaluation of a retention characteristic of a capacitor, the capacitor comprising:
a lower electrode formed on a semiconductor wafer; and
a ferroelectric membrane having a pseudo ohmic contact, the ferroelectric membrane being formed on the lower electrode.
